(19) United States
(12) Patent Application Publication
(10) Pub. No.: US 2002/0151137 A1
(43) Pub. Date: Oct. 17, 2002

(54) Method for semiconductor device planarization

(76) Inventor: Byoung-Ho Kwon, Ichon-shi (KR)

Correspondence Address: JACOBSON HOLMAN, PROFESSIONAL LIMITED LIABILITY COMPANY, 400 SEVENTH STREET, N.W., WASHINGTON, DC, 20004, US

(21) Appl. No.: 09/962,813

(22) Filed: Sep. 26, 2001

(30) Foreign Application Priority Data
Apr. 12, 2001 (KR) 2001-19442

(51) Int. Cl. H01L 21/336

(52) U.S. Cl. 438/260; 438/258; 438/264

(57) ABSTRACT

Disclosed is a method for semiconductor device planarization. The semiconductor manufacturing method includes a memory region and a logic device region, comprising steps of: a) forming first patterns on each regions of the memory and the logic device, respectively; b) forming a first interlayer insulating layer on the memory region and on the logic device region, respectively; c) forming a second pattern on the first inter-layer insulating layer in the memory region; d) forming a second interlayer insulating layer on the memory region and on the logic device region, respectively; e) polishing the second interlayer insulating layer; f) forming a planarization insulating layer on the memory region and on the logic device region; g) removing the planarization insulating layer on the memory region through a selectively etching process; and h) planarizing the memory region and the logic device region through a polishing process.

### FIELD OF THE INVENTION

The present invention relates to a semiconductor manufacturing method; and, more particularly, to a method for semiconductor device planarization.

### DESCRIPTION OF THE PRIOR ART

A merged memory logic (MML) device is a semiconductor device realizing a memory, such as a dynamic random access memory (DRAM) or a static random access memory (SRAM), and a logic device, which controls the memory into one semiconductor device for lightening, high quality and power saving of a system.

The MML device may not be planarized only with a chemical mechanical polishing (hereinafter, referred to as a CMP) because a topology between a memory cell regions, which is formed at least four layers of polysilicon layers, and a logic region, which is formed less than two layers of polysilicon layers, are very large.

Specifically, if the memory region is larger than the logic region, a remnant thickness such as an oxide layer, etc., to be etched by the CMP process in the memory region becomes larger. Topology between the two regions brings about a defocusing problem between the memory region and the logic region in a photolithography process.

Referring to FIGS. 1A to 1C, in a conventional MML device manufacturing process, the thickness difference of a remnant oxide layer problem between a memory region (M) and a logic region (L) is described in detail.

As shown in FIG. 1A, first polysilicon layer patterns (P1) are formed on the semiconductor substrate 10 of the memory and logic regions, and a first interlayer oxide layer 11 is formed on the resulting structure.

Subsequently, second polysilicon layer patterns (P2) are formed on the first interlayer oxide layer 11 of the memory region and a second interlayer oxide layer 12 is formed on the resulting structure. Topology between the memory region (M) and the logic region (L) is generated due to the formation of the second polysilicon layer patterns (P2).

Next, as shown in FIG. 1B, a first CMP processing is carried out to planarize the second interlayer oxide layer 12. In a result of the first CMP process, a topology (A) at a thickness of 3000 Å to 3500 Å is generated between the memory region (M) and the logic region (L).

Subsequently, as shown in FIG. 1C, a third polysilicon layer is formed on the second interlayer oxide layer 12 of the memory region (M) and the logic region (L), and third polysilicon patterns (P3) are formed by applying a photolithography process to the third polysilicon layer.

After that, an interlayer oxide layer (not shown) is formed on the resulting structure and a second CMP processing is carried out for planarization.

As previously described, in each of the first and second CMP processes, a topology is generated at a thickness of 3000 Å to 3500 Å between the memory region (M) and the logic region (L) and, as a result, a topology between the memory region (M) and the logic region (L) may be at a thickness of 6000 Å to 7000 Å after performing the CMP processes twice. The topology may cause a defocusing in a photolithography processing.

FIG. 2 is a graph showing the change of the remnant oxide layer according to the memory cell and the logic device location. As shown in FIG. 2, after performing twice the CMP processes of the interlayer oxide layer, topologies between the logic device region and a memory region are increased.

As previously described, the topology after the CMP processing may be generated according to the density of patterns in each of the memory region and the logic device.

That is, as shown in FIG. 3A, in the logic device region, an interlayer insulating layer 31 is formed within the logic device region both on the relatively high-density pattern region (D1) of metal layers (M) and on the relatively low-density pattern region D2 of a metal layers. Then, as shown in FIG. 3B, the CMP process is performed in the relatively high integration region (D1) so that the inter-layer insulating layer 31 remains relatively thick, thereby to generate a topology between the two regions.

Therefore, in this case, a bad pattern formation is brought out due to a defocusing between the two regions, and an etching processes to form via holes are carried out in different etching depths. Also, an opening or a short is generated due to the differences of etching depth.

### SUMMARY OF THE INVENTION

It is, therefore, an object of the present invention to provide a semiconductor manufacturing method for decreasing topology between two adjacent regions, which have dimensional differences.

It is, therefore, another object of the present invention to provide a semiconductor manufacturing method for decreasing topology caused by a pattern density differences between adjacent regions.

It is, therefore, still another object of the present invention to provide a merged memory logic (MML) device manufacturing method for decreasing topology between a memory region and a logic device region which have dimensional differences in manufacturing the MML device.

In accordance with an aspect of the present invention, there is provided a semiconductor manufacturing method includes a memory region and a logic device region, comprising steps of: a) forming first patterns on each regions of the memory and the logic device, respectively; b) forming a first interlayer insulating layer on the memory region and on the logic device region, respectively; c) forming a second pattern on the first inter-layer insulating layer in the memory region; d) forming a second interlayer insulating layer on the memory region and on the logic device region, respectively; e) polishing the second interlayer insulating layer; f) forming a planarization insulating layer on the memory region and on the logic device region; g) removing the planarization insulating layer on the memory region through a selectively etching process; and h) planarizing the memory region and the logic device region through a polishing process.

In accordance with another aspect of the present invention, there is provided a semiconductor manufacturing method, comprising steps of: a) forming a first interlayer insulating layer on a semiconductor substrate which generates a topology between a first region of relatively high-density patterns and a second region of relatively low-density patterns; b) polishing the first interlayer insulating layer; c) forming a planarization insulating layer on the first and the second regions; d) removing the planarization insulating layer on the first region through a selectively etching process; and e) planarizing the first and the second regions through a polishing process.

For reducing a topology between regions which have differences in area or have a pattern density the present invention has steps of carrying out the CMP to a layer on a resulting structure, removing the planarization insulating layer of an area which has high-density patterns or big area, by selectively etching, and then carrying out a second CMP process to make a planarization.

The present invention relates to a planarization of a merged memory logic device that has dimensional differences in a memory region and a logic device region. First, a chemical mechanical polishing (CMP) is carried out to a layer to be polished on the memory region and the logic region. Next, selectively etching process is applied to the layer to be polished on a relatively high-density memory region, then a second CMP process is carried out to entirely remove a topology on the memory region and the logic device region, thereby accomplishing a planarization.

### BRIEF DESCRIPTION OF THE DRAWINGS

Other objects and aspects of the invention will become apparent from the following description of the embodiments with reference to the accompanying drawings, in which:

FIGS. 1A to 1C are cross-sectional views illustrating a conventional MML device manufacturing process;

FIG. 2 is a graph showing a remnant oxide layer thickness changes according to the location of each of memory cell and logic devices in a conventional MML device;

FIGS. 3A and 3B are cross-sectional views showing a topology according to pattern density of metal layers in a conventional semiconductor device manufacturing process; and

FIGS. 4A to 4F are cross-sectional views showing a MML device manufacturing process in accordance with the present invention.

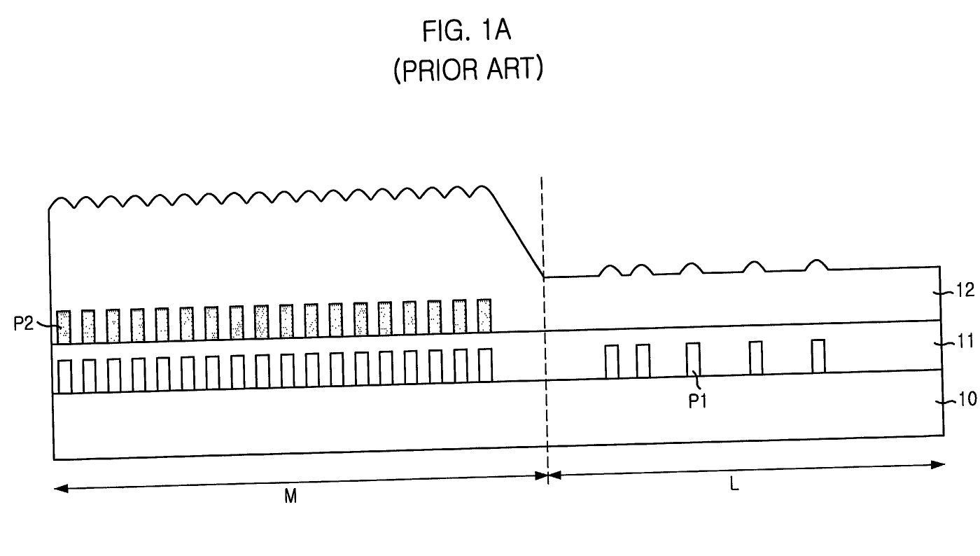

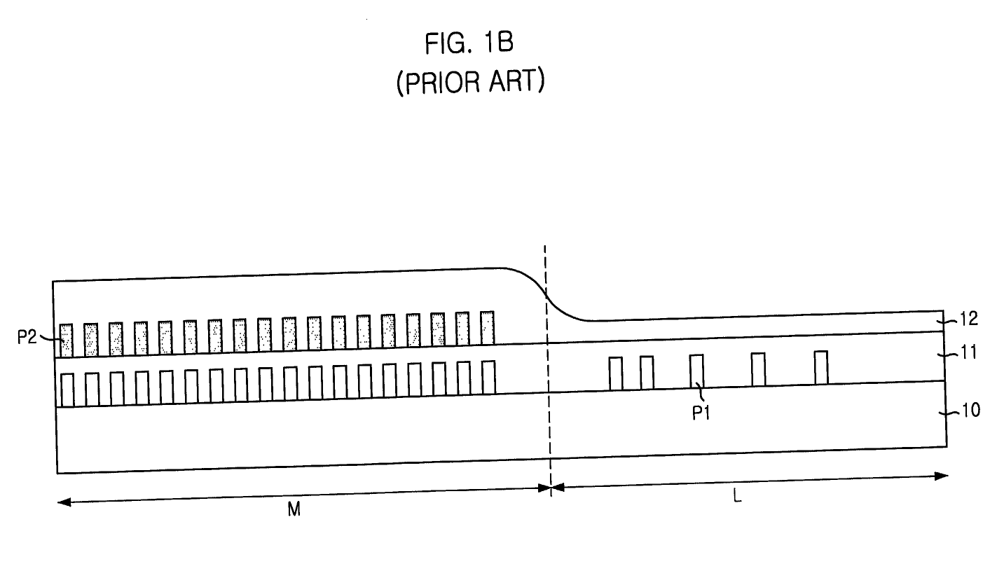

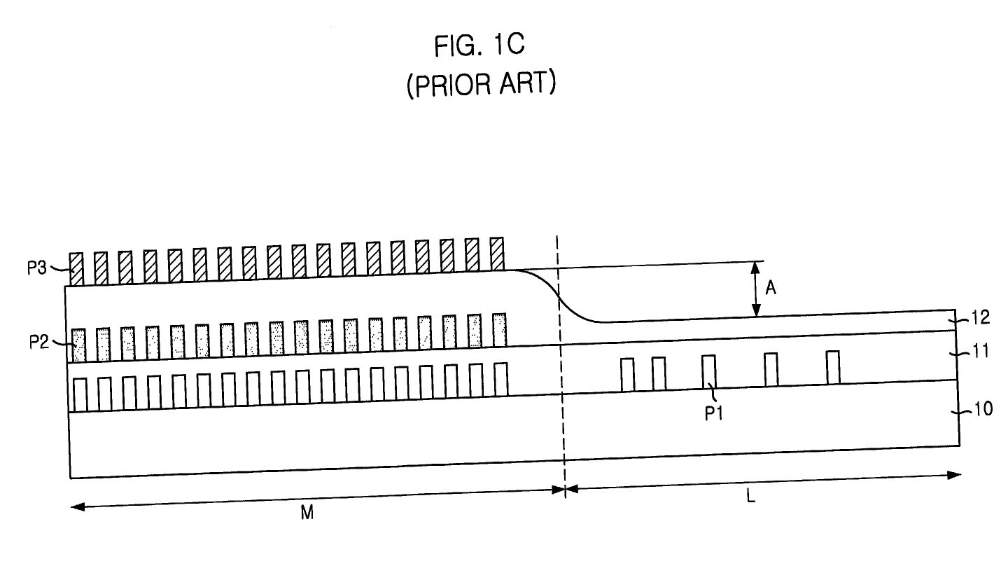

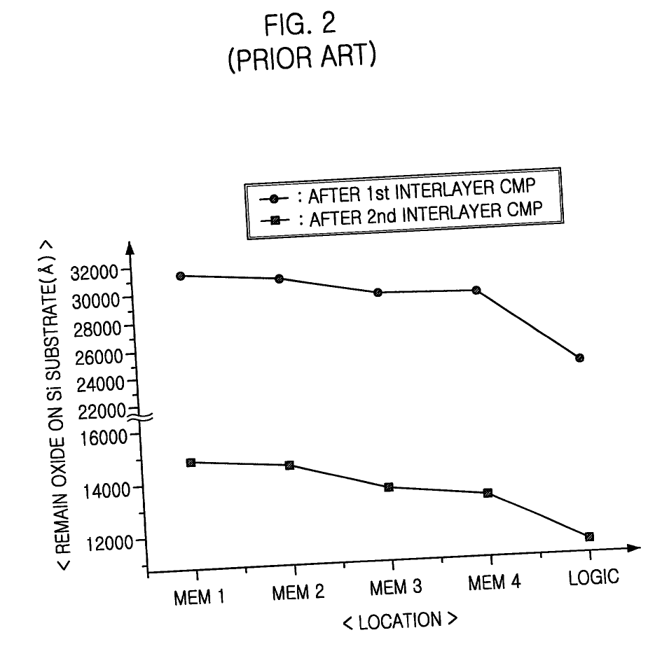

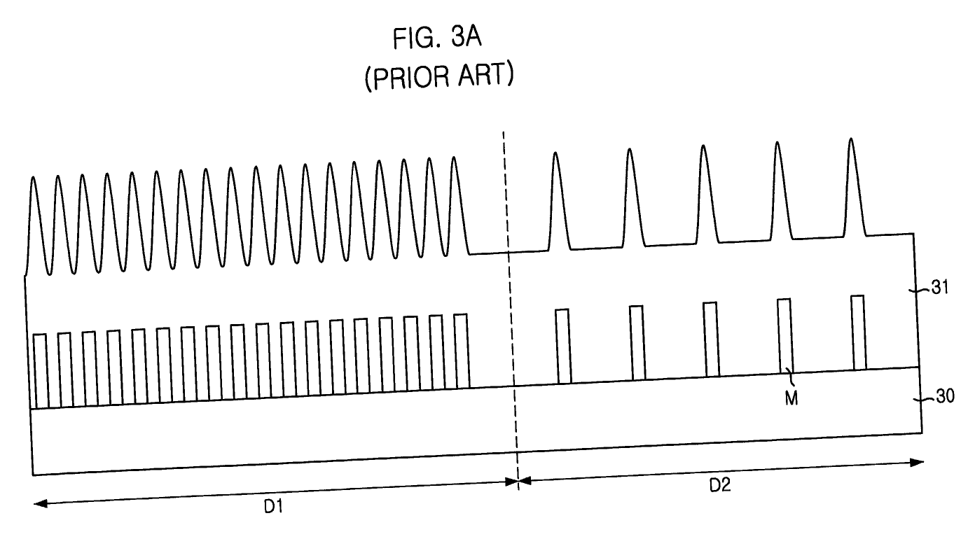

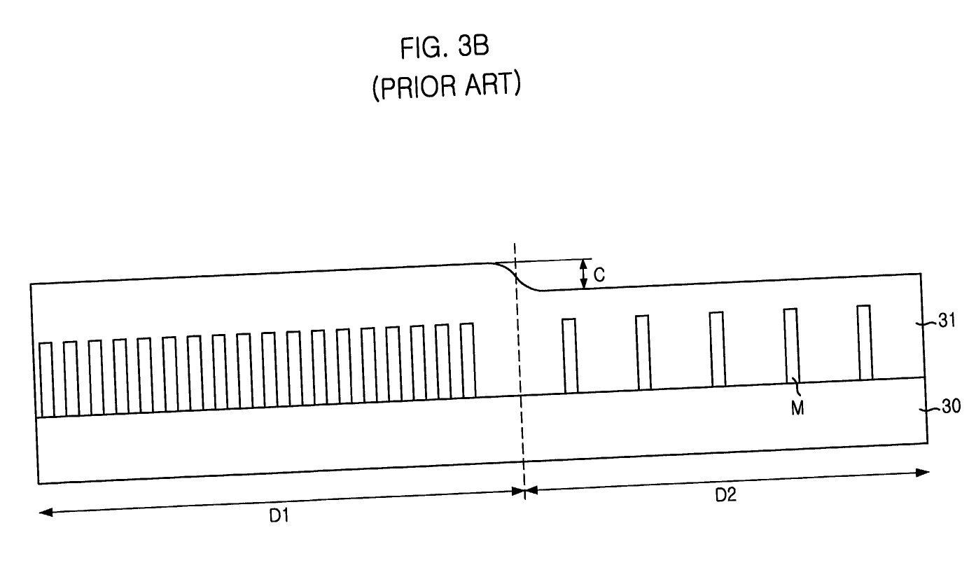

### DETAILED DESCRIPTION OF THE PREFERRED EMBODIMENT

Hereinafter, a semiconductor device planarization according to the present invention will be described in detail referring to the accompanying drawings.

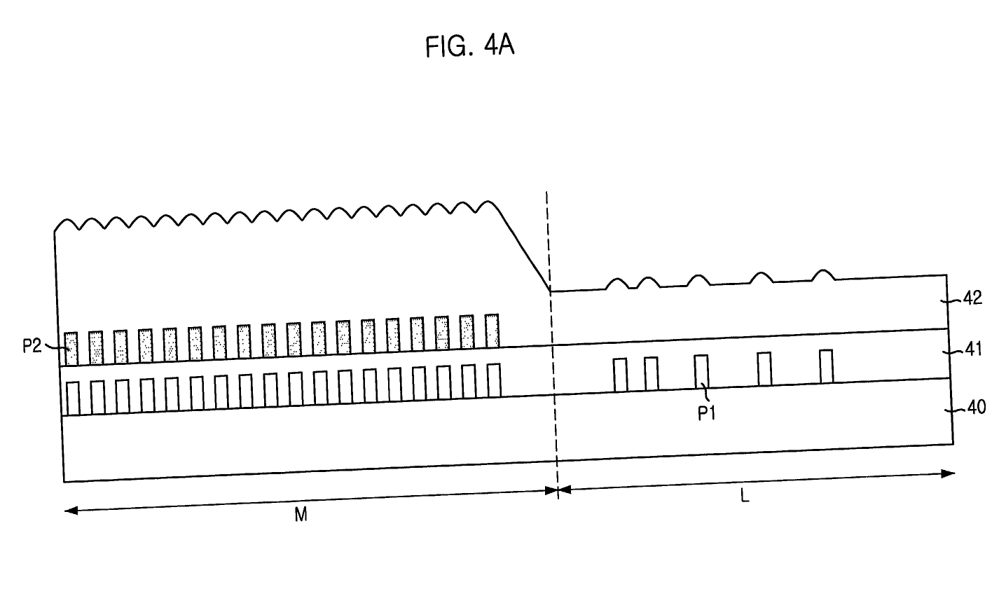

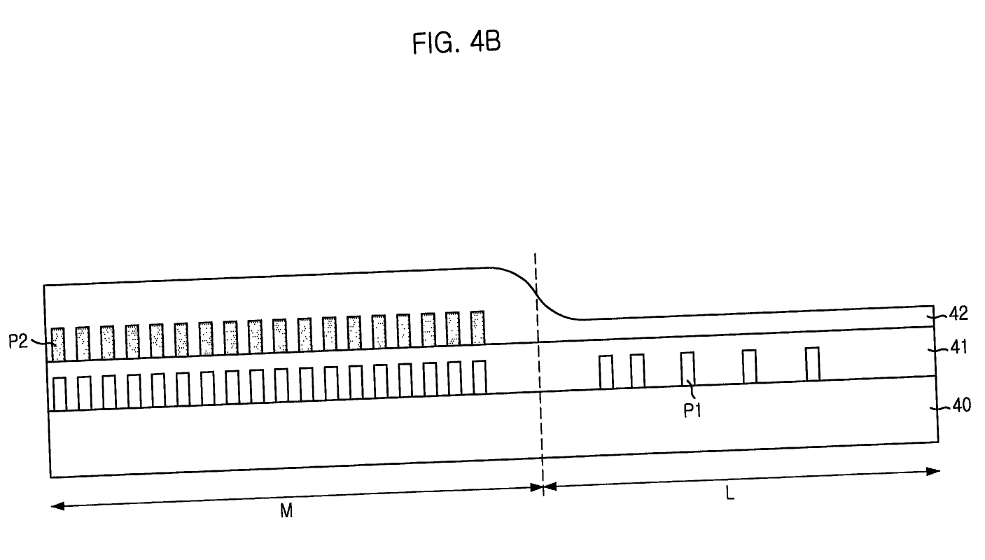

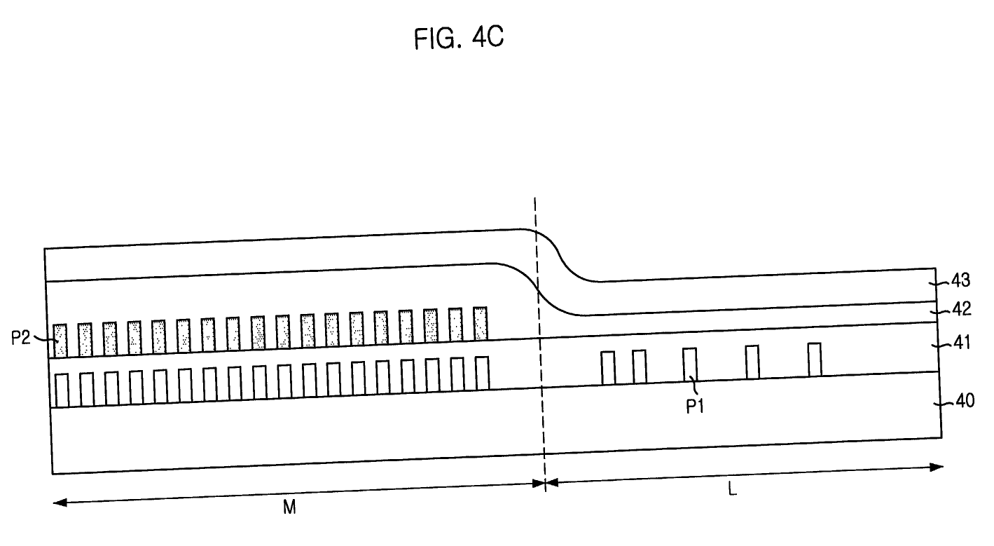

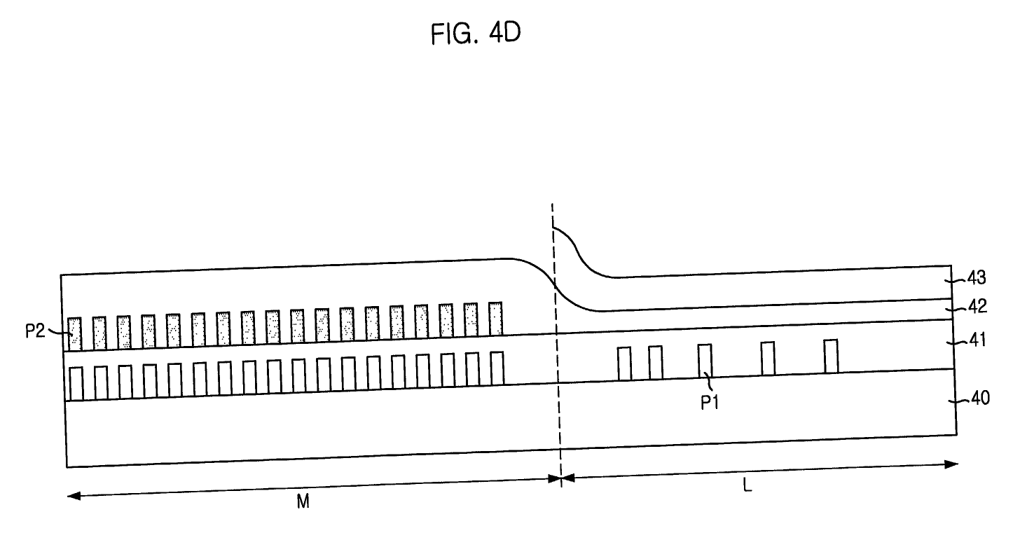

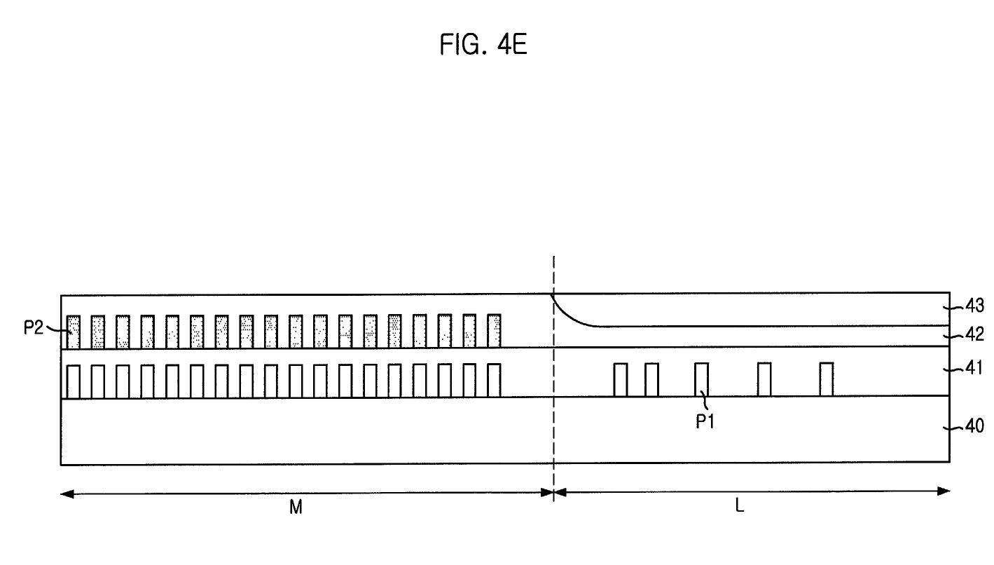

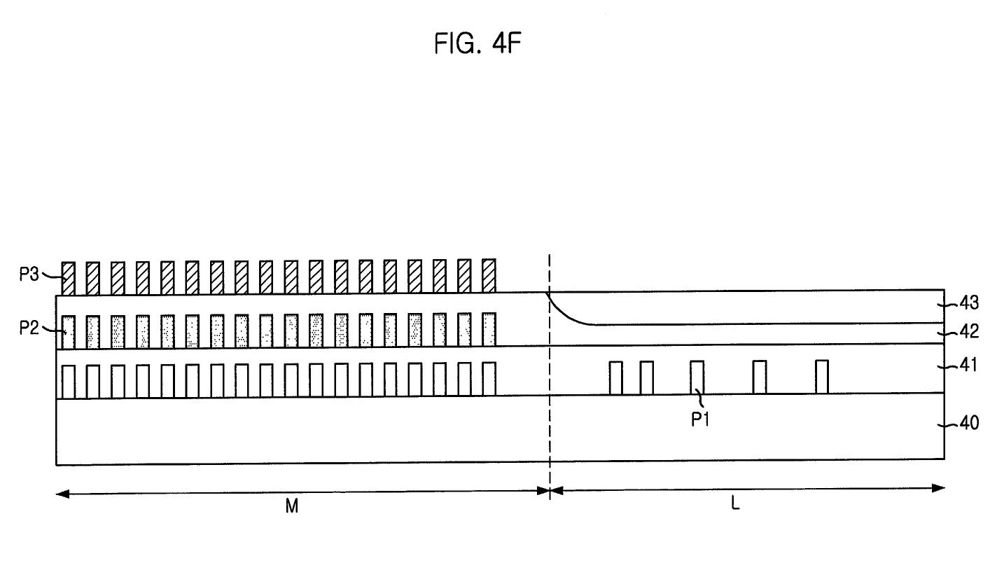

FIGS. 4A to 4F are cross-sectional views showing a MML device manufacturing process in accordance with the present invention.

Referring to FIG. 4A, first polysilicon layer patterns (P1) are formed on a semiconductor substrate 40 of a memory region (M) and a logic region (L) and a first interlayer insulating layer 41 is formed on the result structure with the planarization process. Second polysilicon layer pattern (P2) are formed only on the memory region (M) to require a stacked structure. Subsequently, a second interlayer insulating layer 42 is formed on the result structure. Topology is generated between the memory region (M) and the logic region (L) due to the second polysilicon layer pattern formation.

As shown in FIG. 4B, the second interlayer insulating layer 42 formed on the resulting structure and polished by a first CMP process.

As shown in FIG. 4C, an insulating layer 43, such as an oxide layer, etc., for planarization is formed on the resulting structure. At this time, the thickness of the insulating layer 43 for planarization is thicker than the topology between the memory region (M) and the logic device region (L) and, preferably, the insulating layer 43 is thicker than the topology by about 1000 Å. For example, after the first CMP process, if the topology between the memory region (M) and the logic device region (L) is at a thickness of 3500 Å, the insulating layer 43 for planarization may be formed at a thickness in a range of 4500 Å to 6000 Å.

As shown in FIG. 4D, as an initial step for planarization, the insulating layer 43 on the memory region (M) is selectively removed in order to decrease the topology between the memory region (M) and the logic device region (L).

As shown in FIG. 4E, the second CMP process is carried out to polish the insulating layer 43 at a boundary of the memory region (M) and the logic device region (L).

As shown in FIG. 4F, a third polysilicon layer is formed on the resulting structure and third polysilicon patterns (P3) are formed by carrying out the photolithography process. In the photolithography processing, a defocusing problem is prevented by removing the topology between the memory region (M) and the logic region (L).

The present invention can realize a planarization in a semiconductor device manufacturing process that has differences in the pattern density or has a topology in each region, such as a MML device. With this, a defocusing generated at the following exposure process may be prevented, and a critical dimension (CD) inferiority and cutting or short of a semiconductor device may be solved, thereby increasing an yield.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A semiconductor manufacturing method includes a memory region and a logic device region, comprising steps of:
a) forming first patterns on each regions of the memory and the logic device, respectively;
b) forming a first interlayer insulating layer on the memory region and on the logic device region, respectively;
c) polishing the first interlayer insulating layer;
d) forming a second pattern on the first inter-layer insulating layer in the memory region;
e) forming a second interlayer insulating layer on the memory region and on the logic device region, respectively;
f) polishing the second interlayer insulating layer;
g) forming a planarization insulating layer on the memory region and on the logic device region;
h) removing the planarization insulating layer on the memory region through a selectively etching process; and
i) planarizing the memory region and the logic device region through a polishing process.

2. The method of claim 1, wherein the step f) and the step i) are carried out by a chemical mechanical polishing (CMP), respectively.

3. The method of claim 1, wherein the first interlayer insulating layer, the second interlayer insulating layer and an insulating layer of planarization are formed with an oxide layer, respectively.

4. A semiconductor manufacturing method, comprising steps of:
a) forming a first interlayer insulating layer on a semiconductor substrate which generates a topology between a first region of relatively high-density patterns and a second region of relatively low-density patterns;
b) polishing the first interlayer insulating layer;
c) forming a planarization insulating layer on the first and the second regions;
d) removing the planarization insulating layer on the first region through a selectively etching process; and
e) planarizing the first and the second regions through a polishing process.

5. The method of claim 4, wherein the planarization insulating layer is formed at a thickness in a range of 4500 Å to 6000 Å.

6. The method of claim 4, wherein the step b) and the step e) are carried out a chemical mechanical polishing (CMP) process, respectively.

7. The method of claim 6, wherein the first interlayer insulating layer, the second interlayer insulating layer and an insulating layer for planarization are formed with an oxide layer, respectively.
